(19) United States
(12) Patent Application Publication
(10) Pub. No.: US 2007/0251719 A1
(43) Pub. Date: Nov. 1, 2007

(54) Selective, hermetically sealed microwave package apparatus and methods

(76) Inventor: Rick Sturdivant, Placentia, CA (US)

Correspondence Address: Law Office Of Robert E. Kasody,;Professional Corporation, 6601 Center Drive West #500, Los Angeles, CA, 90045, US

(21) Appl. No.: 11/414,660

(22) Filed: Apr. 27, 2006

(51) Int. Cl. H05K 1/00

(52) U.S. Cl. 174/250

(57) ABSTRACT

A hermetically sealed package for an integrated circuit. In one exemplary embodiment, the package includes a dielectric substrate. At least one conductor is provided having a first conductor surface and a second conductor surface. The second conductor surface is disposed on the dielectric substrate. The first conductor surface comprises at least one electrical contact adapted to couple to the integrated circuit. An insulator layer is provided having a first insulator surface and a second insulator surface. The second insulator surface is deposited on at least one portion of the first conductor surface to substantially insulate the at least one portion of the first conductor surface. A sealant is selectively disposed on at least one portion of the first insulator surface to form a substantially hermetically sealed package.

### BACKGROUND OF THE INVENTION

1. Field of the Invention

The invention relates generally to the field of sealed packages, and specifically in one exemplary aspect to hermetically sealed packages for electronic components.

2. Description of Related Technology

Hermetically sealed packages are well known in the art. Such packages are used to protect electronic components, such as integrated circuit amplifiers or mixers, from moisture and other environmental conditions. Hermetically sealed packages normally include some sort of a metal box. The metal box generally has an opening to insert electronic components and chips. Electronic components are attached, such as by a conductive or non-conductive epoxy, to the floor of the metal box. A lid may be laser welded to the metal box to substantially seal the box so as to somewhat limit exposure of the electronic components to any additional contaminates or impurities and may also provide electromagnetic shielding. Afterwards, impurities, typically nitrogen and oxygen, are purged from, e.g., pumped from, the metal box. Generally, an electric pump attached to an opening in the box pumps out impurities to achieve a desired hermeticity level. After pumping is completed, the opening is sealed.

However, this method is somewhat labor-intensive and not cost effective when required to produce a large volume of hermetically sealed, electronic components. For instance, a military application, such as a phase array electronic transceiver/signal switching network used for global positioning system (GPS), may require hermetically sealing a large volume of integrated circuits used as a portion of phased array antenna circuitry. For example, the packaging of thousands of Monolithic Microwave Integrated Circuits (MMIC's) would be a somewhat expensive and labor intensive process because each circuit would require individual placement and attachment within an individual metal box, sealing of the individual metal boxes, and extraction of any impurities therefrom. Furthermore, the use of a metal box increases package size, and this is undesirable where a small footprint package is necessary for integrating many packaged integrated circuits in an electronic product, such as a reduced area, phased array antenna having a multitude of array elements and integrated circuits coupled to each or many of these array elements.

As another example, an integrated circuit may be hermetically sealed using the following procedure: mounting the integrated circuit on a substrate made from an alumina or duroid material; positioning a metal lid over the integrated circuit so to cover and protect the integrated circuit, and solder welding lips of the metal lid to a metal trace on the substrate. This exemplary method is generally representative of such prior art methods and apparatus, e.g., U.S. Pat. No. 5,699,611 to Kurogi et al. issued Dec. 23, 1997, and entitled “Method of Hermetically Self-Sealing A Flip Chip,” or U.S. Pat. No. 5,579,874 to Kurogi et al. issued on Nov. 26, 1996, and entitled “Hermetically Self-Sealing Flip Chip”, each of the foregoing being incorporated herein by reference in its entirety. However, such methods are somewhat labor intensive because each integrated circuit requires a lid. Furthermore, because the solder welding of the lips of the lid to the substrate involves a high temperature process, the packaging process may degrade RF circuit performance.

As yet another example, a hermetic sealing process may involve sealing the entire chip during wafer production. See US patent publication No. 2006/0022337 to Farnworth et al. published Feb. 2, 2006, entitled “Hermetic Chip in Wafer Form,” incorporated herein by reference in its entirety, which is generally representative of such prior art approaches. In another example, a semiconductor wafer is hermetically sealed by fabricating special metal frame structures on the back and/or front sides of the chips. See US patent publication No. 2006/0043601 to Pahl et al. published Mar. 2, 2006, entitled “Hermetically Encapsulated Component and Waferscale Method for the Production Thereof,” incorporated herein by reference in its entirety, which is generally representative of such prior art techniques. In summary, both of the foregoing methods involve somewhat complicated and elaborate wafer fabrication steps, which may increase integrated circuit costs, where the cost increase would be passed on to a consumer in the form of increased RF module production costs.

Thus, what is needed are improved apparatus and methods that permit hermetic sealing of one or more integrated circuits, would provide the ability to reduce packaging size, decrease costs, and provide the desired frequency range of operation, e.g., high frequencies such as microwave or millimeter wave frequencies. Such improved apparatus and methods would also be useful for producing hermetically sealed microwave circuit transition networks that provide low-loss transmission of RF electrical signals from a substrate material into a hermetically sealed package.

### SUMMARY OF THE INVENTION

In a first aspect of the present invention, a microelectronics package for an integrated circuit is disclosed. In one embodiment, the package provides a dielectric substrate. At least one conductor is also provided having a first conductor surface and a second conductor surface. The second conductor surface is disposed on the dielectric substrate, and the first conductor surface comprises at least one electrical contact adapted to couple to the integrated circuit. An insulator layer has a first insulator surface and a second insulator surface. The second insulator surface is deposited on at least one portion of the first conductor surface to substantially insulate the at least one portion of the first conductor surface. A sealant is selectively disposed on at least one portion of the first insulator surface to form a substantially hermetically sealed package.

In a second aspect of the present invention, a method is disclosed for producing a substantially hermetically sealed package for an integrated circuit. In one embodiment, the method comprises: providing a dielectric substrate; disposing a second conductor surface of a conductor on at least one portion of the dielectric substrate; and disposing at least one electrical contact on a first conductor surface of the conductor adapted to couple to the integrated circuit. The exemplary method further includes: disposing a second insulator surface of an insulator on at least one portion of the conductor to substantially insulate the at least one portion of the first conductor surface; disposing the integrated circuit on the at least one electrical contact; and disposing a sealant on at least one portion of a first insulator surface to form a substantially hermetically sealed package.

In a third aspect of the present invention, a substantially hermetically sealed, surface mount package useful to mount a flip chip is disclosed. In one embodiment, the package comprises a dielectric substrate having at least one via aperture that supports RF signal transmission from a top substrate surface to a bottom substrate surface. A RF feed structure is configured for RF signals transmission from the top substrate surface to the flip chip and coupled to the flip chip. An insulator layer is disposed on the RF feed structure. A sealant is disposed on the RF feed structure and disposed so as to cover edges of the flip chip and exposed portions of the insulator layer.

In a fourth aspect of the present invention, an apparatus is disclosed for hermetically sealing and testing a plurality of semiconductor chips. In one embodiment, the apparatus comprises a plurality of dielectric substrates. Each of the dielectric substrates includes: an integrated circuit mounted on the dielectric substrate; at least one via to communicate RF signals from a top surface to a bottom surface of the dielectric substrate; an input RF feed and output RF feed to couple RF signals from the top surface to the integrated circuit; an insulator layer disposed on the input and the output RF feeds; and a sealant disposed on an exposed portion of the insulator layer and edges of the integrated circuit to form a hermetically sealed package. In this embodiment, a testing substrate is provided for disposing the plurality of dielectric substrates. RF testing connections are also provided by metal conductive balls that connect to at least one via on at least one of the top and the bottom surfaces.

In a fifth embodiment of the present invention, an apparatus for testing hermeticity of a microelectronics package is disclosed. In one embodiment, the apparatus comprises a pulse energy source to transmit a pulse of energy through an integrated circuit disposed in the package having a first side and a second side. A first transducer is disposed substantially proximal to the first side of the package and configured to receive and measure a transmission energy spectrum a hermetically sealed volume emits from the package. In addition, a second transducer is disposed substantially proximal to the second side of the package and configured to measure a reflection energy spectrum a hermetically sealed volume emits from the package. Furthermore, a spectrum analyzer is provided that is configured to analyze at least one of the transmission or reflection energy spectrums to determine a hermeticity level of the volume.

In a sixth aspect of the present invention, a method is disclosed for testing the hermeticity of a microelectronics package. In one embodiment, the method comprises transmitting a pulse of energy through an integrated circuit disposed in the package having a first side and a second side. The method further comprises measuring a transmission energy spectrum a hermetically sealed volume emits at a first transducer disposed proximal to a first side of the package. Also included in this exemplary method are the steps of measuring a reflection energy spectrum the volume emits at a second transducer disposed proximal to a second side of the package; and analyzing at least one of the transmission or reflection energy spectrums to determine a hermeticity level of the volume.

These and other objects, embodiments, aspects, advantages, and features of the present invention will be set forth in part in the description which follows, and in part will become apparent to those skilled in the art by reference to the following description of the invention and referenced drawings or by practice of the invention. The objects, aspects, advantages, and features of the invention are realized and attained by means of the instrumentalities, procedures, and combinations particularly pointed out in the appended claims.

### BRIEF DESCRIPTION OF THE DRAWINGS

FIG. 1 is a cut-away front elevation view of a microelectronics package utilizing an insulating layer and glass sealant in accordance with a first embodiment of the present invention.

FIG. 2 is a cut-away front elevation view of a microelectronics package having a lid attached by utilizing an insulating layer and glass sealant in accordance with one embodiment of the present invention.

FIG. 3 is cut-away front elevation view of a microelectronics package in accordance with another embodiment of the present invention.

FIG. 4 is a cut-away front elevation view of an apparatus for measuring hermeticity of a microelectronics package in accordance with an embodiment of the present invention.

FIG. 5 is a logical flow diagram illustrating one exemplary embodiment of the method for producing a substantially hermetically sealed package in accordance with the present invention.

FIG. 6 is a logical flow diagram illustrating one exemplary embodiment of the method for measuring hermeticity level of a microelectronics package according to the present invention.

### DETAILED DESCRIPTION

Reference is now made to the drawings wherein like numerals refer to like parts throughout.

As used herein, the term “integrated circuit” refers without limitation to any set of complex electronic components or their interconnections, such as a microstrip circuit transition, that are etched or otherwise formed on a chip or microelectronic computer circuit incorporated into a chip or a semiconductor or a whole system. The chip may contain a single component or a microelectronic semiconductor device consisting of interconnected transistors and other components. The chip or IC may be, for example constructed (“fabricated”) on a small area (a “die”) cut from, e.g., a Silicon (or special applications, Sapphire), Gallium Arsenide (GaAs), Silicon Germanium (SiGe) or Indium Phosphide wafer. The IC may be classified, for example, into analogue, digital, or hybrid (both analogue and digital on the same chip). Digital integrated circuits may contain anything from one to millions of logic gates, invertors, and, or, nand, and nor gates, flipflops, multiplexors, etc. on a few square millimeters. Some examples of these digital integrated circuits include, without limitation, memory devices (e.g., DRAM, SRAM, DDRAM, EEPROM/Flash, ROM, MEMS, RFIC, MMIC), digital processors, SoC devices, FPGAs, ASICs, DAC's, transceivers, memory controllers, and other devices, as well as combinations thereofs. The small size of these circuits allows high speed, low power dissipation, and reduced manufacturing cost compared with board-level integration.

Furthermore, the term “hermetically sealed package” refers without limitation to a package that is substantially sealed against, e.g., the escape or entry of air.

Overview

In one salient aspect, the present invention discloses apparatus and methods for packaging of integrated circuit(s) for, inter alia, creating a substantially hermetically sealed package. In particular, an improved microelectronics package is disclosed; the package provides a sealing layer structure (e.g., using an insulator layer and a sealant) for providing a hermetic seal for an integrated circuit mounted thereon. The package advantageously provides for selectively applying the sealing layer structure, thereby allowing an integrated circuit to be mounted on a substrate and substantially hermetically sealed without the need for mounting the integrated circuit in a box, which may be somewhat expensive and labor-intensive to fabricate. Accordingly, the apparatus and methods of the invention afford a very significant reduction in cost over the prior art for a component having similar or identical electrical/radio-frequency performance.

These improved apparatus and methods further provide significant improvement in terms of hermetic packaging operations performed in large volume IC applications. Large volume applications may include, inter alia, a large electronic network array, such as a phased array antenna mounted on a substrate, which contains hundreds of integrated circuit to assist with adaptive electronic beam steering. In addition, the ability of the improved apparatus and methods provides significant flexibility to a user testing hermetic seals of packages; e.g., those of a large microelectronics array mounted to a substrate, such as an array of integrated circuit amplifiers mounted to a ceramic substrate or board.

Furthermore, the improved microelectronics packaging techniques disclosed herein provide a small package size and allow wideband, microwave and RF performance for transmission of electrical signals from the substrate into the package. Additionally, the improved microelectronics packaging techniques provide for wafer level packaging and hermetic sealing of integrated circuits prior to singulation (e.g., separating individual integrated circuits from the wafer, using techniques such as sawing or scribe and breaking).

Exemplary Extension Apparatus

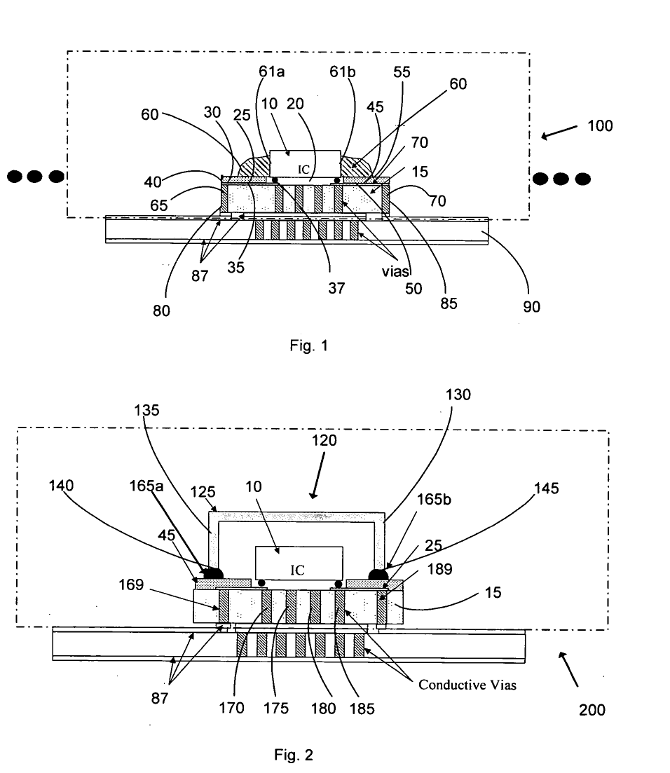

Referring now to FIGS. 1-4, exemplary embodiments of the microelectronics package of the invention are described in detail. It will be appreciated that while described primarily in the context of packaging an integrated circuit, at least portions of the apparatus and methods described herein may be used in other applications, such as for example and without limitation, transducers, sensors, electrical connectors, wafer-level MEMS packaging, optoelectronics, fiber communication systems, MMIC, RFIC, or the like.

Moreover, it will be recognized that the present invention may find utility beyond purely hermeticity concerns. For example, the “sealing layer structure” described subsequently herein may conceivably be utilized to improve other microelectronics circuit functionality; e.g., helping to increase electrical isolation properties of an integrated circuit which circuit may be prone to or sensitive to “coupling from adjacent circuit structures”, such as a frequency resonant element, dielectric resonator, inductive coil, microstrip antenna radiating patch elements, static charge, etc., or the like. Other functions might include protection of an integrated circuit during subsequent fabrication or module assembly (e.g., for purposes of providing a barrier for substrate mounted integrated circuits to prevent electrical performance degradation during subsequent chemical or photolithography steps required for microelectronic module completion, and so forth). Myriad other functions will be recognized by those of ordinary skill in the art given the present disclosure.

FIG. 1 is a cut-away front elevation view of a microelectronics package 100 utilizing an insulating layer and glass sealant in accordance with a first embodiment of the present invention. While in a controlled environment, e.g. such as in chamber having a helium rich environment, a clean room, or the like, the microelectronics package 100 is fabricated or manufactured. The microelectronics package 100 protects an integrated circuit 10, e.g., a flip chip, from contaminants, such as air, to prevent circuit degradation and/or failure. The package 100 includes a dielectric substrate 15, for example constructed of Alumina (Al₂O₃), Alumina Nitride, Beryllium Oxide (BeO₂), Liquid Crystal Polymer, or the like, having a portion 20 to dispose the integrated circuit 10. A conductive material 25, e.g., an RF transmission line or the like, is further provided having a first conductor surface 30 and a second conductor surface 35. In this example, the conductive material 25 having a first conductor surface 30 and a second conductor surface 35 forms a 50 ohm impedance transmission line. The first and second conductor surfaces 30, 35 are, for example, constructed of a single metal, e.g., gold, copper, or tin, or a mixture comprising several metals. The second conductor surface 35 is disposed on the dielectric substrate 15, and the first conductor surface 30 includes at least one electrical contact, e.g., a solder bump, solder ball, conductive bump or ball bump, as indicated by element 37 in FIG. 1, adapted to couple to the integrated circuit 10.

An insulator layer 45, e.g., having a first insulator surface 55 and a second insulator surface 50, is deposited on the conductive material 25. The insulator layer 45 is a protective dielectric layer, such as a thick film printed dielectric, a ceramic tape material, e.g., transfer tape, or the like. In this exemplary example, the insulator 45 is a dielectric, which is a high temperature paste, applied utilizing a temperature, e.g., a second value temperature, within a preferred range of 500 degrees C. (Celsius) to 900 degrees C. (Celsius). In one alternative, the dielectric is applied using a more preferred temperature range of 500 degrees C. (Celsius) to 700 degrees C. (Celsius). Furthermore, the insulator layer 45 is deposited, for example, by applying as a coating or paste, on the conductive material 25 and on at least one portion of the first conductor surface 30 to substantially insulate the at least one portion of the first conductor surface 30. Furthermore, the insulator layer 45 is a low loss material to RF signals, e.g., prevents RF loss by not substantially disturbing and/or absorbing RF field energy propagated by the conductive material 25, while acting as an insulator for non-RF signals. An integrated circuit 10, for example a flip chip, is disposed, e.g., using a conductive bump such as a solder bump, hard bump, or ball bump.

The package 100, in this example, has RF input and output edge vias 65, 70 disposed respectively on a first edge 80 and a second edge 85 of the dielectric substrate 15 to reduce effective ground capacitance. Furthermore, during the fabrication process, the package 100 is generally attached using a conductive epoxy 87, such as a solder-based epoxy, at lower edges of the RF edge vias 65, 70 so that multiple, integrated circuits may be tested simultaneously mounted on a motherboard 90, e.g., an alumina substrate. In this exemplary illustration, only the package 100 is shown. The motherboard 90 may provide testing of multiple, packaged integrated circuits in a prescribed manner or fashion, such as testing in a row and/or column format of integrated circuits, such as one or more of the integrated circuit 10, each having package 100. Furthermore, this mounting procedure may allow multiple integrated circuits being processed and substantially hermetically sealed during a relatively similar processing procedure or time period so as to reduce integrated circuit packaging time.

A sealant 60 is selectively disposed on one portion of the first insulator surface 55 to form a barrier that provides a substantially hermetically sealed package. The sealant 60, for example, may comprise a solder glass sealant. In this example, the solder glass sealant is deposited on the insulator layer 45 and along edges 61a, 61b of the integrated circuit 10. To complete the deposition process, the sealant 60 is reflowed using a low temperature, e.g., a first value temperature, preferably within the range of 100 to 400 degrees C. (Celsius), with a more preferred temperature range of 320 to 350 degrees C. (Celsius). Furthermore, the solder glass sealant 60 may be reflowed using laser heating to substantially hermetically seal the package. In the context of the present embodiment, a substantially hermetically sealed package comprises, without limitation, a package that is substantially sealed, especially against the escape or entry of air. For example, such a sealed package may be one that has a volume of air that is on the order of 1.28×10⁻⁵ cubic inches of air. It will be appreciated that while the sealant shown is a solder glass sealant, other materials may conceivably be used with equal success, including a solder glass, any similar glass material, liquid crystal polymer, or the like, as recognized by those of ordinary skill in the art given the present disclosure.

One advantage of this approach, versus prior RF packaging approaches, is that the insulator layer 45 is deposited using a high application temperature while the integrated circuit 10 is not installed on the dielectric substrate 15; thus, the integrated circuit 10 is protected from a high temperature process that may degrade its RF signal performance parameters such as signal gain, input and/or output return loss, and overall lifespan. As a consequence, the low reflow temperature of the sealant 60 in combination with the insulator layer 45 substantially hermetically seals the RF performance integrated circuit 10 while substantially maintaining original, on-wafer tested RF performance of the integrated circuit 10. Another advantage of this process is the solder sealant 60 abuts proximate opposing ends 61a, 61b of the integrated circuit 10, e.g., a flip chip, only so that only a minimal amount of sealant is required to hermetically seal the flip chip.

Furthermore, no metal box is required to hermetically seal the flip chip so that a real estate area occupied by an integrated circuit 10 that is packaged is minimized. Another advantage of this package is the conductive material 25 that provides low loss RF signal connectivity to a RF feed through, e.g., RF input edge via 65 or RF output edge via 70. Still another advantage of this package is that one electrical contact, e.g., conductive bump such as a solder bump, hard bump, or ball bump 37, lies along a co-planar direction with the conductive material 25, e.g., a transmission-line, so that the integrated circuit 10 may be mounted to the dielectric substrate 15 using standard surface mount techniques. Therefore, the package provides a simplified interface for integrated circuit packaging, assembly and/or low-cost mass production.

FIG. 2 is a cut-away front elevation view of a package 200 having a lid 120 being attached using an insulating layer 45 and glass sealant 165a, 165b in accordance with an embodiment of the present invention. The package 200 is an alternative embodiment of the package 100, which utilizes a lid 120 to protect the integrated circuit 100. In particular, the package 200 includes a lid 120 having a top 125, a first side 135, and second side 130. The lid 120 may be fabricated from metal, such as gold, copper, or tin, a composite thereof or a ceramic material, or any like material recognized by those skilled in the art. In this example, an end 140 of the first side 135 and an end 145 of the second side 130 contact the sealant 165a, 165b to form a substantially hermetically sealed package. In this example, the integrated circuit 10, e.g., a flip chip, is substantially hermetically sealed.

The sealant 165a, 165b is a similar composition and has similar characteristics as that of the sealant 60. More specifically, the exemplary sealant 165a, 165b comprises a solder glass sealant. In this example, the solder glass sealant is deposited on the insulator layer 45 and reflowed using a low temperature, e.g., preferably 100 to 400 degrees C. (Celsius), with a more preferred temperature range of 320 to 350 degrees C. (Celsius). Furthermore, the solder glass sealant 165a, 165b may be reflowed using laser heating or reflow oven to substantially hermetically seal the package. It will be appreciated that while the sealant shown is a solder glass sealant, other materials may conceivably be used with equal success, including a solder glass, any similar glass material, liquid crystal polymer, or the like, as recognized by those of ordinary skill in the art given the present disclosure.

One advantage of this embodiment is that the package 200 may further include hermetic or non-hermetic vias 169, 170, 175, 180, 185, 189 disposed within the dielectric substrate 15. The insulator layer provides a substantially hermetically sealed package for these non-hermetic vias. Furthermore, similar to the embodiment described in FIG. 1, the sealant 165a, 165b is a solder glass sealant that reflows over the insulator layer 45 utilizing a low reflow temperature and the insulator layer 45 is a dielectric coating, similar to those described in FIG. 1, applied using a high application temperature. Furthermore, the low reflow temperature, e.g., a first value temperature, and the high application temperature, e.g., a second value temperature, are as described with reference to FIG. 1, e.g., the low reflow temperature being less than 400 degrees C., and the high application temperature being greater than 500 degrees C. and less than 900 degrees C.

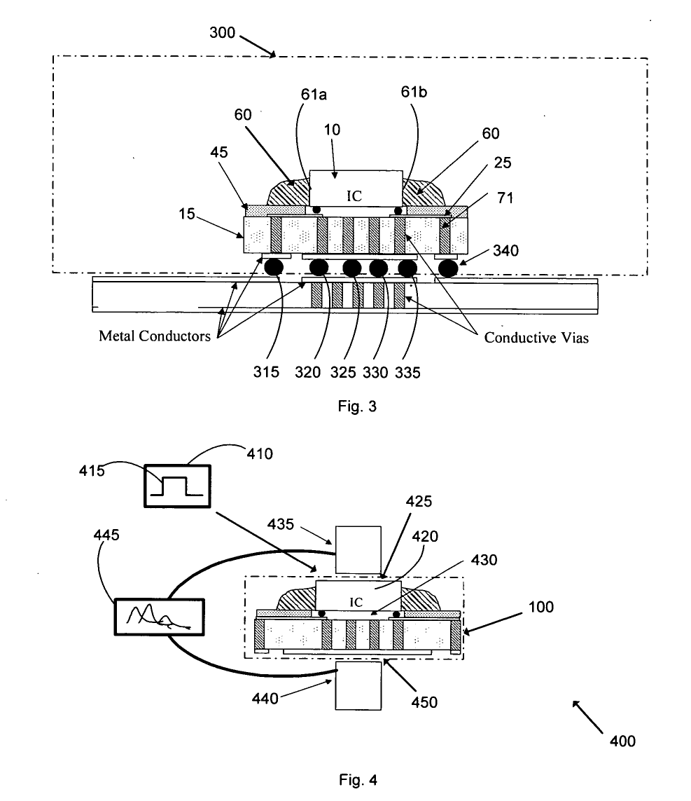

FIG. 3 is cut-away front elevation view of a substantially hermetically sealed, package 300 in accordance with an embodiment of the present invention. In this embodiment, similar to that of FIG. 1, a sealant 60 is deposited on the insulator 45 and edges 61a, 61b of the integrated circuit 10. However, the difference is that the interconnection between a motherboard 310 and the substrate 15 is formed using solder balls 315, 320, 325, 330, 335, and 340.

FIG. 4 is a cut-away front elevation view of an apparatus for measuring hermeticity of a microelectronics package 100 in accordance with an embodiment of the present invention. An apparatus 400 has been disclosed for testing hermeticity of a microelectronics package 100. The apparatus 400 includes a pulse energy source 410, e.g., an ultrasonic pulse energy source, that transmits a pulse of energy 415 through an integrated circuit 420 disposed in the package 400, where the package 400 has a first side 425 and a second side 450. A first transducer 435, e.g., an ultrasonic transducer or the like as recognized by those of ordinary skill in the art, is disposed proximal to the first side 425 of the package 100 to receive and measure a transmission energy spectrum emitted by a hermetically sealed volume 430. A second transducer 440, e.g., an ultrasonic transducer or the like as recognized by another of ordinary skill in the art, is disposed proximal to a second side 450 of the package 400 to measure a reflection of the energy spectrum from a hermetically sealed volume.

A spectrum analyzer 445 analyzes at least one of the transmission or reflection energy spectrums to determine a hermeticity level of the volume 430. Consequently, a hermeticity level is determined of the volume 430 involves determining if a gas, e.g., a helium rich gas or the like as recognized by those of ordinary skill in the art, originally utilized in hermetically sealing the volume 430 being detected at a substantially similar level to an original hermeticity package sealing level. For example, if the hermetic sealing process is completed utilizing a specific gas during the sealing process, e.g., helium rich, during the sealing process, then the reflection energy spectrum detected from the volume 430 will contain the specific gas, e.g., helium rich, utilized during the sealing process. Otherwise, if the volume 430 detected contains some other gas, e.g., air, then it will be known that the hermetic seal of the package 100 has been damaged and is leaking.

Furthermore, the transmission and reflection energy spectrums may be correlated, utilizing generally signal processing methods by analyzing an electrical equivalent representation, e.g., electrical energy peaks and/or complex electrical signal characteristics, corresponding to a chemical composition of the volume 430. For example, electrical energy peaks may used to determine a hermeticity level of the package 100. As a consequence, in the following example, if a substantially similar original hermeticity level of the volume 430 is detected, then the hermetic seal would be found to be intact. In this same alternative embodiment, the integrated circuit is a flip chip, a pulse of energy is ultrasonic, and the transducer is an ultrasonic transducer.

Exemplary Methods

Referring now to FIG. 1-4, an exemplary embodiment of the method for utilizing the aforementioned extension apparatus is described. While described primarily in the context of the exemplary embodiments of the package 100, 200, and 300 and the testing apparatus 400 as shown in FIGS. 1-4, it will be appreciated that the methodology presented herein may be readily adapted to any different configuration of the packages 100, 200, and 300 and the apparatus 400 by those of ordinary skill.

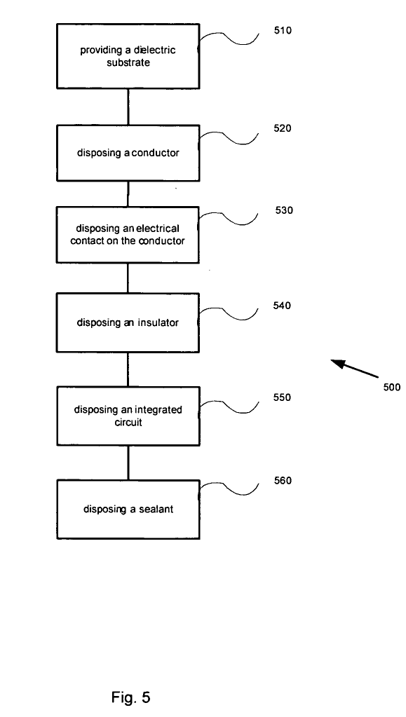

As shown in FIG. 5, the exemplary method 500 comprises providing a dielectric substrate 15 (step 510). In one alternative embodiment of step 510, a dielectric substrate 15 is deposited, and within the dielectric substrate 15 at least one edge via (e.g., 65, 70) for RF electrical signal flow is provided along at least one edge of the dielectric substrate 15 to achieve a reduced stray capacitance RF signal path. In yet another alternative embodiment of step 510, a dielectric substrate 15 is provided, and hermetic or non-hermetic vias (e.g., 170, 175, 180, and 185) are disposed within the dielectric substrate 15.

At least one portion of an insulator is disposed on a second conductor surface of a conductor (step 520). In one alternative embodiment of step 530, disposing the insulator 45 comprises applying a dielectric paste using an application temperature greater than 500 degrees C. and less than 900 degrees C.

Next, at least one electrical contact is disposed on a first conductor surface 30 of the conductor 25 adapted to couple to the integrated circuit 10 (step 530). In one alternative embodiment of step 530, disposing at least one electrical contact (e.g., 37) comprises depositing at least one conductive bump, e.g., a solder bump, hard bump, or ball bump. In one alternative embodiment of step 530, depositing at least one electrical contact (e.g., 37) comprises depositing at least one electrical contact to lie along a co-planar direction with the at least one transmission-line (e.g., 25) and the integrated circuit 10 to mount the integrated circuit 10 utilizing surface mount techniques.

Following, a second insulator surface 50 of an insulator 45 is disposed on at least one portion of the conductor, e.g., 25, to substantially insulate the at least one portion of the first conductor surface 30 (step 540). In another alternative embodiment of step 540, disposing the insulator 45 comprises depositing a dielectric paste having a second value temperature.

Next, the integrated circuit 10 is disposed on the at least one electrical contact (e.g., 37) (step 550). In another alternative embodiment of step 550, a flip chip 10 is mounted on the at least one electrical contact (e.g., 37).

Lastly, a sealant 60 is disposed on at least one portion of a first insulator surface 55 to form a substantially hermetically sealed package (step 560). In an alternative embodiment of step 560, disposing a sealant 60 comprises reflowing a sealant 60 having a reflow temperature (e.g., a first value temperature) being less than the application temperature (e.g., a second value temperature occurring during deposition of the insulator 45). In yet an alternative embodiment of step 560, disposing a sealant 60 comprises reflowing a glass sealant having a reflow temperature, e.g., a first value temperature. In another alternative embodiment of step 560, disposing a sealant 60 comprises reflowing a glass sealant using a reflow temperature, e.g. a first value temperature, less than 400 degrees and greater than 100 degrees C. In another alternative embodiment of step 560, disposing a glass sealant 60 comprises reflowing a glass sealant 60 having a reflow temperature to substantially cover opposing edges 61a, 61b of the flip chip 10 to form a substantially hermetically sealed package.

In yet another alternative embodiment of step 560, depositing the solder glass sealant 60 comprises reflowing the solder glass using a laser to cover opposing edges of the flip chip 10 and to hermetically seal the flip chip 10. In an alternative embodiment of step 560, a lid 120 is deposited having a top 125, first side 135, and second side 130. More specifically, an end 140 of the first side 135 and an end 145 of the second side 130 contact the sealant 60 to form a substantially hermetically sealed package, and the sealant 60 is a solder glass sealant that has a reflow temperature less than 400 degrees C. and greater than 100 degrees C.

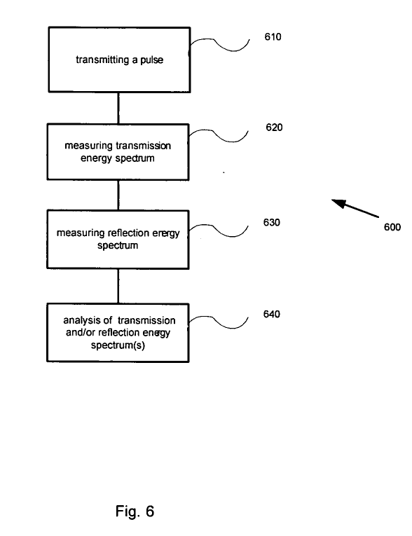

As shown in FIG. 6, the exemplary method 600 comprises transmitting a pulse of energy 415 through an integrated circuit 420 disposed in the package 100 having a first side 425 and a second side 450 (step 610). In one alternative embodiment of step 610, transmitting a pulse of energy 415 comprises transmitting an ultrasonic pulse of energy.

Next, a transmission energy spectrum emitted by a hermetically sealed volume 430 is measured at the first transducer 435 proximal to on a first side 425 of the package 100 (step 620). In one alternative embodiment of step 620, measuring a transmission energy spectrum comprises measuring a transmission energy spectrum utilizing an ultrasonic transducer.

Following, a reflection of the energy spectrum emitted by a hermetically sealed volume 430 is measured at a second transducer 440 disposed proximal to a second side 450 of the package 100 (step 630). In one alternative embodiment of step 630, measuring a reflection comprises measuring a reflection utilizing an ultrasonic transducer.

At least one of the transmission or reflection energy spectrums is analyzed to determine a hermeticity level of the volume 430 (step 640). In one alternative embodiment of step 640, determining a hermeticity level of the volume 430 involves determining if a gas originally utilized in hermetically sealing the volume 430 is detected at a substantially similar level to that at an original hermeticity package sealing. In one alternative embodiment of step 640, the transmission and reflection energy spectrums are correlated to determine a package hermeticity level. In this alternative embodiment of step 640, the integrated circuit comprises a flip chip, a pulse of energy comprises ultrasonic, and the transducer comprises an ultrasonic transducer.

It will be appreciated that while certain aspects of the invention have been described in terms of a specific sequence of steps of a method, these descriptions are only illustrative of the broader methods of the invention, and may be modified as required by the particular application. Certain steps may be rendered unnecessary or optional under certain circumstances. Additionally, certain steps or functionality may be added to the disclosed embodiments, or the order of performance of two or more steps permuted. All such variations are considered to be encompassed within the invention disclosed and claimed herein.

While the above detailed description has shown, described, and pointed out novel features of the invention as applied to various embodiments, it will be understood that various omissions, substitutions, and changes in the form and details of the device or process illustrated may be made by those skilled in the art without departing from the invention. The foregoing description is of the best mode presently contemplated of carrying out the invention. This description is in no way meant to be limiting, but rather should be taken as illustrative of the general principles of the invention. The scope of the invention should be determined with reference to the claims.

What is claimed is:

1. A package for an integrated circuit, comprising:
a dielectric substrate;
at least one conductor having a first conductor surface and a second conductor surface;
wherein the second conductor surface is disposed on the dielectric substrate, and the first conductor surface comprises at least one electrical contact adapted to couple to the integrated circuit;
an insulator layer having a first insulator surface and a second insulator surface;
wherein the second insulator surface is deposited on at least one portion of the first conductor surface to substantially insulate the at least one portion of the first conductor surface; and
a sealant selectively disposed on at least one portion of the first insulator surface to form a substantially hermetically sealed package.

2. The package of claim 1, wherein the sealant has a reflow temperature of a first value temperature, the insulator layer has an application temperature of a second value temperature, and the first value temperature being less than the second value temperature.

3. The package of claim 1, wherein the sealant comprises a glass sealant deposited utilizing a first value temperature, the insulator layer comprising a dielectric coating deposited utilizing a second value temperature, and the first value temperature being less than the second value temperature.

4. The package of claim 1, wherein the sealant comprises a glass sealant having a reflow temperature, the reflow temperature being less than 400 degrees C., the insulator layer comprising a dielectric coating having an application temperature, and the application temperature being greater than 500 degrees C. and less than 700 degrees C.

5. The package of claim 1, wherein the sealant comprises a glass sealant having a reflow temperature between 300 and 400 degrees C. and the insulator layer comprises a dielectric coating having an application temperature greater than 400 degrees and less than 800 degrees.

6. The package of claim 1, wherein the integrated circuit comprises a flip chip and the at least one electrical contact comprises a conductive bump

7. The package of claim 6, wherein the sealant comprises a solder glass sealant that substantially abuts proximate to opposing ends of the flip chip to form a hermetically sealed, flip chip package.

8. The package of claim 7, wherein the solder glass sealant is reflowed using laser heating or reflow oven to substantially hermetically seal the package.

9. The package of claim 1, wherein the at least one conductor comprises at least one transmission-line, and the at least one electrical contact lies along a substantially co-planar direction with the at least one transmission-line and the integrated circuit so as to allow the integrated circuit to be mounted to the dielectric substrate using a conductive bump technique.

10. The package of claim 9, further comprising:
at least one edge via for RF electrical signal flow disposed at least proximate to at least one of a first edge and a second edge of the dielectric substrate;
wherein said at least one edge via reduces effective ground capacitance; and
wherein the sealant comprises a glass sealant having a reflow temperature less than 400 degrees C.

11. The package of claim 1, further comprising:
at least one edge via for RF electrical signal flow disposed proximate a first edge and a second edge of the dielectric substrate so as to achieve an improved RF performance due at least in part to reducing effective capacitance to ground;
wherein:
the integrated circuit comprises a flip chip;
the at least one electrical contact comprises a conductive bump;
the insulator layer comprises a dielectric coating having an application temperature;
the sealant comprises a solder sealant having a reflow temperature, the reflow temperature being substantially less than the application temperature; and
wherein the solder sealant substantially abuts opposing ends of the flip chip and an exposed portion of the insulator layer.

12. The package of claim 1, further comprising a lid having a top, first side, and second side;
wherein an end of the first side and an end of the second side contact the sealant to form a substantially hermetically sealed package; and
wherein the sealant comprises a solder glass sealant that has a reflow temperature less than 400 degrees C.

13. The package of claim 8, further comprising non-hermetic vias disposed within the dielectric substrate;
wherein the sealant comprises a solder glass sealant adapted to reflow over the insulator layer at a reflow temperature; and
wherein the insulator layer comprises a dielectric coating applied at an application temperature, the reflow temperature being less than 400 degrees C. and the application temperature being greater than 500 degrees C. and less than 800 degrees, and said insulating layer substantially hermetically seals the non-hermetic vias.

14. A method for producing a hermetically sealed package for use with an integrated circuit, comprising the steps of:
providing a dielectric substrate;
disposing at least one electrical contact on a first conductor surface of a conductor adapted to couple to the integrated circuit;
disposing a second conductor surface of the conductor on at least one portion of the dielectric substrate;
disposing a second insulator surface of an insulator on at least one portion of the conductor to substantially insulate the at least one portion of the first conductor surface;
disposing the integrated circuit on the at least one electrical contact; and
disposing a sealant on at least one portion of a first insulator surface to form a substantially hermetically sealed package.

15. The method of claim 14, wherein disposing a sealant comprises reflowing a sealant having a reflow temperature.

16. The method of claim 15, wherein disposing the insulator material comprises depositing a dielectric paste having an application temperature, the reflow temperature being less than the application temperature.

17. The method of claim 14, wherein disposing a sealant comprises reflowing a glass sealant using a reflow temperature less than 400 degrees, and disposing the insulator material comprises applying a dielectric paste using an application temperature greater than 500 degrees C. and less than 900 degrees C.

18. The method of claim 14, wherein:
the step of disposing an integrated circuit comprises mounting a flip chip;
the step of disposing at least one electrical contact comprises depositing at least one conductive bump;
the step of disposing an insulator comprises depositing a dielectric coating utilizing an application temperature; and
the step of disposing a glass sealant comprises reflowing a glass sealant having a reflow temperature to substantially cover opposing edges of the flip chip.

19. The method of claim 16, wherein the step of disposing the integrated circuit comprises depositing a flip chip, and the step of disposing a sealant comprises reflowing a solder glass sealant using a laser or reflow oven to cover opposing edges of the flip chip and to hermetically seal the flip chip.

20. The method of claim 14, wherein the step of disposing a second conductor surface of the conductor comprises depositing at least one transmission-line, and the step of disposing at least one electrical contact comprises depositing at least one electrical contact to lie substantially co-planar with the at least one transmission-line and the integrated circuit to allow the integrated circuit to be mounted to the dielectric substrate using surface mount techniques.

21. The method of claim 15, further comprising the step of:
disposing at least one edge via for RF electrical signal flow along at least one edge of the dielectric substrate to achieve a reduced stray capacitance RF signal path between the dielectric substrate and the at least one transmission-line.

22. The method of claim 14, further comprising the step of:
disposing at least one edge via for RF electrical signal flow proximate a first edge and a second edge of the dielectric substrate so as to reduce effective capacitance to ground;
wherein the integrated circuit comprises a flip chip, the at least one electrical contact comprises a conductive bump, the insulator layer comprises a dielectric coating having an application temperature, the sealant comprises a glass sealant having a reflow temperature;
wherein the application temperature is greater than the reflow temperature; and
wherein the solder sealant covers opposing edges of the flip chip and an exposed portion of the insulator layer to hermetically seal the package.

23. The method of claim 14, further comprising the step of depositing a lid having a top, first side, and second side;
wherein an end of the first side and an end of the second side contact the sealant to form a substantially hermetically sealed package; and
wherein the sealant comprises a solder glass sealant that has a reflow temperature less than 400 degrees C. and greater than 100 degrees C.

24. The method of claim 14, further comprising the step of disposing non-hermetic vias within the dielectric substrate;
wherein the insulator layer provides a substantially hermetically sealed package for the non-hermetic vias, the sealant comprises a solder glass sealant that reflows over the insulator layer and covers edges of the integrated circuit utilizing a reflow temperature less than 400 degrees C., and the insulator layer comprises a dielectric coating applied using an application temperature greater than 500 degrees C. and less than 900 degrees C.

25. A substantially hermetically sealed, surface mount package useful to mount a flip chip, comprising:
a dielectric substrate having at least one via aperture that supports RF signal transmission from a top substrate surface to a bottom substrate surface;
a RF feed structure coupled to the flip chip and configured for RF signal transmission from the top substrate surface to the flip chip;
an insulator layer disposed on the RF feed structure; and
a sealant disposed on the RF feed structure and disposed so as to cover edges of the flip chip and exposed portions of the insulator layer.

26. The package of claim 25, wherein the sealant comprises a glass sealant having a reflow temperature less than 400 degrees C., and the insulator layer comprises a dielectric coating having an application temperature greater than 500 degrees C. and less than 900 degrees C.

27. The package of claim 25, further comprising:
at least one edge via configured to permit RF electrical signal flow and disposed on a first edge and a second edge of the dielectric substrate so as to reduce effective capacitance to ground;
wherein the at least one electrical contact comprises a conductive bump, the insulator layer comprises a dielectric coating having an application temperature, the sealant comprises a solder sealant having a reflow temperature, and the application temperature is greater than the reflow temperature.

28. The package of claim 25, wherein the dielectric substrate is selected from the group consisting of: alumina, alumina oxide, alumina nitride, and beryllium oxide, the insulating layer is selected from the group consisting of: thick film printed dielectric, ceramic tape, liquid crystal polymer, and alumina, and the sealant is selected from the group consisting of: solder glass sealant, glass sealant, and liquid crystal polymer.

29. An apparatus for hermetically sealing and testing a plurality of semiconductor chips, comprising:
a plurality of dielectric substrates each comprising:
an integrated circuit mounted on the dielectric substrate;
at least one via to communicate (Radio Frequency) RF signals between a bottom surface and a top surface of the dielectric substrate;
an input RF feed and output RF feed to couple RF signals from the top surface to the integrated circuit;
an insulator layer disposed on the input and the output RF feeds; and
a sealant disposed on an exposed portion of the insulator layer and edges of the integrated circuit to form a hermetically sealed package; and
a testing substrate for disposing the plurality of dielectric substrates;
wherein RF testing connections are provided by metal conductive balls that connect to vias on at least one of the top and the bottom surfaces.

30. The apparatus of claim 29, wherein the at least one via is an RF edge via disposed on an edge of at least one of the plurality of dielectric substrates so as to reduce the overall package size.

31. The apparatus of claim 29, wherein the sealant comprises a glass sealant having a reflow temperature, the reflow temperature being less than 400 degrees C., and the insulator layer comprises a dielectric coating having an application temperature, the application temperature being greater than 500 degrees C. and less than 900 degrees C.

32. The apparatus of claim 29, further comprising:
at least one edge via for RF electrical signal flow between the at least one edge via and at least one of the input RF feed and the output RF feed, the at least one edge via is disposed proximal to at least one of a first edge and a second edge of the dielectric substrate to achieve an improved RF performance so as to reduce effective capacitance to ground;
wherein the at least one electrical contact comprises a conductive bump, the insulator layer comprises a dielectric coating deposited using a second value temperature; the sealant comprises a solder sealant deposited using a first value temperature, and the second value temperature being greater than the first value temperature.

33. The apparatus of claim 29, wherein the dielectric substrate is selected from the group consisting of: alumina, alumina oxide, alumina nitride, and beryllium oxide; the insulating layer is selected from the group consisting of: thick film printed dielectric, ceramic tape, liquid crystal polymer, and alumina; and the sealant is selected from the group consisting of: solder glass sealant, glass sealant, and liquid crystal polymer.

34. An apparatus for testing hermeticity of a microelectronics package, comprising:
a pulse energy source to transmit a pulse of energy through an integrated circuit disposed in the package having a first side and a second side;
a first transducer disposed substantially proximal to the first side of the package and configured to measure a transmission energy spectrum a hermetically sealed volume emits from the package;
a second transducer disposed substantially proximal to a second side of the package and configured to measure a reflection energy spectrum a hermetically sealed volume emits from the package; and
a spectrum analyzer configured to analyze at least one of the transmission or reflection energy spectrums to determine a hermeticity level of the volume.

35. The apparatus of claim 34, wherein a first transducer comprises an ultrasonic transducer.

36. The apparatus of claim 34, wherein a second transducer comprises an ultrasonic transducer.

37. The apparatus of claim 34, wherein to determine a hermeticity level of the volume comprises to determine if a gas originally utilized in hermetically sealing the volume is detected at a substantially similar level to that at an original hermeticity package sealing level.

38. The apparatus of claim 34, wherein the transmission and reflection energy spectrums are correlated to determine a package hermeticity level.

39. The apparatus of claim 34, wherein the pulse energy source comprises an ultrasonic pulse energy source.

40. The apparatus of claim 34, wherein to determine a hermeticity level of the volume comprises to determine if a gas originally utilized in hermetically sealing the volume is detected at a substantially similar level to that at original hermeticity package sealing; and
wherein the integrated circuit comprises a flip chip, a pulse of energy comprises ultrasonic, and the transducer comprises an ultrasonic transducer.

41. A method for testing hermeticity of a microelectronics package, comprising:
transmitting a pulse of energy through an integrated circuit disposed in the package having a first side and a second side;
measuring a transmission energy spectrum a hermetically sealed volume emits at a first transducer disposed proximal to the first side;
measuring a reflection of the energy spectrum the volume emits at a second transducer disposed proximal to the second side; and
analyzing at least one of the transmission or reflection energy spectrums to determine a hermeticity level of the volume.

42. The method of claim 41, wherein measuring a reflection energy spectrum comprises measuring a reflection energy spectrum utilizing an ultrasonic transducer.

43. The method of claim 41, wherein measuring a transmission energy spectrum comprises measuring a transmission energy spectrum utilizing an ultrasonic transducer.

44. The method of claim 41, wherein to determine a hermeticity level of the volume comprises to determine if a gas originally utilized in hermetically sealing the volume is detected at a substantially similar level to that level while hermeticity sealing the package.

45. The method of claim 41, wherein the transmission and reflection energy spectrums are correlated to determine an effective package hermeticity level.

46. The method of claim 41, wherein transmitting a pulse of energy comprises transmitting an ultrasonic pulse of energy.

47. The method of claim 41, wherein to determine a hermeticity level of the volume comprises to determine if a gas originally utilized in hermetically sealing the volume is detected at a substantially similar level to that at an original hermeticity package sealing.

48. The method of claim 47, wherein the integrated circuit comprises a flip chip, a pulse of energy comprises ultrasonic, and the transducer comprises an ultrasonic transducer.
